(19) United States
(12) Patent Application Publication
(10) Pub. No.: US 2004/0137269 A1
(43) Pub. Date: Jul. 15, 2004

(54) Polymeric substrate for display and light emitting devices

(76) Inventors: Grant Hay, Evansville, IN (US); Marc Schaepkens, Ballston Lake, NY (US); Zhaohui Su, Evansville, IN (US); Parfait Jean Marie Likibi, Newburgh, IN (US); Nicholas Donald Abbatiello, Dalton, MA (US); James Alan Mahood, Evansville, IN (US)

Correspondence Address: General Electric Company, CRD Patent Docket Rm 4A59, Bldg. K1, P.O. Box 8, Schenectady, NY, 12301, US

(21) Appl. No.: 10/743,240

(22) Filed: Dec. 22, 2003

Related U.S. Application Data
(62) Division of application No. 10/134,050, filed on Apr. 29, 2002.

(51) Int. Cl. B32B 9/00

(52) U.S. Cl. 428/690

(57) ABSTRACT

A polymeric substrate comprising a high glass transition temperature polycarbonate for use in optical display devices and light emitting devices is provided in the present invention. A liquid crystal display, an organic electroluminescent device, and methods for use including the aforementioned polymeric substrate are also provided in the present invention.

### BACKGROUND OF THE INVENTION

The present invention relates generally to a polymeric substrate. More particularly, the present invention relates to a polymeric substrate for flat-panel displays and next generation lighting applications.

Optical displays such as active-matrix liquid-crystal displays (LCDs) and light emitting devices such as organic electroluminescent devices (OELDs) are widely used for different applications. LCDs are widely used as displays for applications such as high-end laptop computers. OELDs offer significant potential for use in general illumination applications such as graphic display and imaging art. Unfortunately, many liquid crystal materials and organic electroluminescent materials undergo detrimental reactions with oxygen and moisture. To function over extended periods of time the LCD device and OELD were typically built on glass substrates because of the low permeability of glass to oxygen and water vapor. However, glass substrates are not suitable for certain applications in which flexibility is desired. The attractive design opportunities offered by flat and flexible displays as well as their low-cost manufacturing potential have led to significant interest in polymer-based displays.

A number of layers are typically present on the LCD and the OELD. The material to be deposited, the density of the deposited material, and the deposition temperature, typically determines the deposition of the various layers. For example, a method for deposition can be a high temperature sputtering process. This results in the need for a plastic substrate having a high glass transition temperature to maintain its integrity during high temperature deposition.

Accordingly, there is a need in the art for a high glass transition temperature polymer-based transparent flexible material for use with display devices and light emitting devices.

### SUMMARY OF THE INVENTION

The present invention provides a polymeric substrate comprising formula (I):

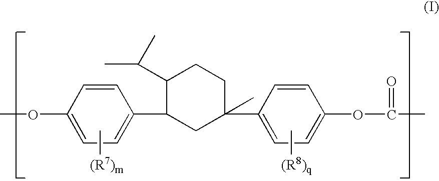

where the three optically active sites of (I) can be R isomers, S isomers, or combinations thereof;

R⁷ and R⁸ are independently selected from the group consisting of C₁-C₆ alkyl and hydrogen;

m is an integer in a range between about 1 and about 4;

q is an integer in a range between about 1 and about 4; and

wherein the polymeric substrate is used in an optical display device or light emitting device.

In another embodiment, the present invention further provides a method for using a polymeric substrate comprising disposing said polymeric substrate in an optical display device or a light emitting device, wherein said polymeric substrate comprises formula (I).

In yet another embodiment, the present invention further provides a liquid crystal display comprising:

a) two polymeric substrates, said two polymeric substrates being substantially parallel to each other, wherein each polymeric substrate comprises formula (I);

b) a transparent conductive layer disposed on a surface of each of said polymeric substrate; and

c) a liquid crystal material, said liquid crystal material being disposed between said two polymeric substrates, such that said liquid crystal material contacts said transparent conductive layer on each of said two substrates.

In yet a further embodiment, the present invention provides an organic electroluminescent device comprising

(a) a polymeric substrate wherein said polymeric substrate comprises formula (I); and

(b) an organic electroluminescent layer disposed on the polymeric substrate, wherein the organic electroluminescent layer comprises an organic electroluminescent material disposed between two electrodes.

### BRIEF DESCRIPTION OF THE DRAWINGS

FIG. 1 is a graphic depiction of the % transmission of BHPM-PC versus wavelength.

### DETAILED DESCRIPTION OF THE INVENTION

In this specification and in the claims that follow, reference will be made to a number of terms that shall be defined to have the following meaning.

The singular forms “a”, “an” and “the” include plural referents unless the context clearly dictates otherwise.

“Optional” or “optionally” mean that the subsequently described event or circumstance may or may not occur, and that the description includes instances where said event or circumstance occurs and instances where it does not.

In optical display and light emitting devices, substrates are the base material on which subsequent layers are situated. In the present invention, it was unexpectedly found that an isotropic polymeric substrate comprising a polycarbonate disclosed herein exhibits a high glass transition temperature, favorable haze, and uniform thickness which make the polycarbonate ideal for optical display devices and light emitting devices. Specifically, the polycarbonate is ideal for high temperature display and light emitting applications, for example, for use in liquid crystal displays (LCDs) or organic electroluminescent devices (OELDs). “Favorable haze” as used herein refers to an average haze percent less than about 4%. “Uniform thickness” as used herein refers to a thickness that does not vary by more than ±3%.

The isotropic polymeric substrate of the present invention has the formula (I):

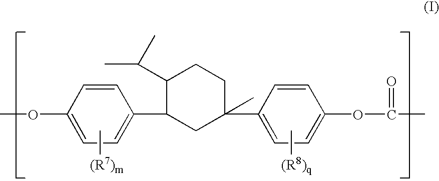

where the three optically active sites of (I) can be R isomers, S isomers, or combinations thereof;

R⁷ and R⁸ are independently selected from the group consisting of C₁-C₆ alkyl and hydrogen;

m is an integer in a range between about 1 and about 4; and

q is an integer in a range between about 1 and about 4. The molecular weight of the polymer of the present invention is typically in a range between about 30,000 and about 100,000. In optical display applications and light emitting devices, the substrate typically has a thickness less than about 0.5 millimeters (mm), more typically less than about 0.2 mm, and most typically, less than about 0.1 mm.

Polymeric substrates of formula (I) typically have sufficient optical clarity and a retardation of about ±100 nm or less. The polymeric substrates of formula (I) are also substantially transparent. “Substantially transparent” as used herein refers to a transparency of at least 80% in the visible light range of the spectrum. Additionally, the plastic is capable of withstanding subsequent processing parameters (e.g., application of subsequent layers) such as sputtering temperatures of about room temperature (about 25° C. or lower) to 200° C., and subsequent storage conditions (e.g., in a hot car having temperatures up to about 70° C.). That is, the plastic has sufficient thermal stability to prevent deformation during the various layer deposition steps as well as during storage by the end-user. Typically, materials having glass transition temperatures greater than about 200° C. should be employed in display applications and light emitting devices. The polymeric substrate of formula (I) has a glass transition temperature greater than about 235° C.

Typically, a liquid crystal display comprises a center liquid crystal layer, a first and a second conductive layer, a first and second barrier coating layer, and a first and a second polymeric substrate. When the barrier layer is present, it may be present on at least one surface of the polymeric substrate or on both surfaces of the polymeric substrate. In an exemplary liquid crystal display, first polymeric substrate, first barrier layer and first conductive layer combine to form a first plate and second polymeric substrate, second barrier layer, and second conductive layer combine to form a second plate. First and second plates are disposed substantially parallel to one another and the liquid crystal layer is interposed therebetween. Hence, the first and second polymeric substrates are typically the outermost layers. Typically, each polymeric substrate has a thickness less than about 0.5 millimeters (mm), more typically less than about 0.2 mm, and most typically, less than about 0.1 mm.

The liquid crystal layer is typically comprised of nematic liquid crystals (NLCs), thermochromic liquid crystals (TLCs), liotropic liquid crystals (LLCs), ferroelectric liquid crystals (FLCs), twisted nematic liquid crystals (TNLCs), super-twisted nematic liquid crystals (STNLCs), polymer-dispersed liquid crystals (PDLCs), cholesteric liquid crystals (CTLC), or the like.

The conductive layers should be made of a substantially transparent conductive material, typically a class II or class III oxide. Preferably, the conductive layers comprise indium tin oxide (ITO). Alternatively, the conductive layers may comprise at least one of tin oxides, cadmium oxides, indium oxides, magnesium oxides, gallium oxides, zinc oxides, germanium oxides, and combinations thereof. The oxides that may be used in conductive layers include, but are not limited to: (GaIn)₂O₃; CdSn₂O₄; CdGa₂O₄; CdInO₄; CdSb₂O₆; CdGeO₄; In₂O₃, MgIn₂O₃; MgIn₂O₄; ZnO; ZnSnO₃; Zn₂SnO₄; Zn₂InO₅; and ZnIn₂O₆. The oxides may also contain small amounts of at least one dopant. For example, (GaIn)₂O₃ may be doped with either Sn or Ge, In₂O₃ may be doped with Ga, and ZnO may be doped with either aluminum or gallium. Alternatively, the conductive layers may comprise thin transparent metallic films of at least one of Al, Cu, Pt, Pd, and alloys thereof.

In one embodiment, the conductive layers have a thickness in the range between about 10 nm to about 200 nm. Typically, the conductive layers are deposited using, for example, sputtering, evaporation, ion beam assisted deposition (IBAD), plasma enhanced chemical vapor deposition (PEVCD), expanding thermal plasma CVD (ETPCVD), high intensity plasma chemical vapor deposition (HIPCVD) using either an inductively coupled plasma (ICP) or electron cyclotron resonance (ECR), combinations thereof, or the like. The choice of deposition technique for the transparent conductor layer is based on the material to be deposited, density of the deposited material, and deposition temperature.

When the barrier layer is a single layer, it is constructed of either a substantially transparent organic material or a substantially transparent inorganic material. When the barrier layer is multilayer, the barrier layer is constructed of at least one layer of a substantially transparent organic material and at least one layer of a substantially transparent inorganic material having low permeability of oxygen, water vapor, and other reactive materials present in the environment. By “low permeability,” it is meant that the permeability of oxygen or other reactive gases is less than about 1 cm³ (at standard temperature and pressure)/m²/day/atm, and the permeability of water vapor is less than about 1 g/m²/day. The permeation rates of moisture, oxygen, and other reactive materials decrease as the number of alternating layers increases. The organic layers reduce the permeation rates of gases through barrier by reducing the number of straight-through paths resulting from defects in the inorganic layers upon which or under which the organic layer is formed. When the barrier layer includes more than one organic layer and more than one inorganic layer, different organic and inorganic materials may be advantageously used for the individual layers. The thickness of each inorganic layer is typically in the range from about 1 to about 500 nm, preferably from about 10 nm to about 100 nm, and that of an organic layer typically about 1 to about 10000 nm, preferably from about 10 nm to about 5000 nm. The organic layer may be formed, for example, by physical vapor deposition, chemical vapor deposition (CVD), deposition from flash-evaporated materials, dip coating, or spray coating of the monomer, followed by polymerization, and the like. Physical or chemical vapor deposition may be desirably conducted under a subatmospheric pressure, for example, to minimize an introduction of unwanted molecules in the growing layers. The inorganic layer may be formed, for example, by physical vapor deposition, chemical vapor deposition, ion beam-assisted deposition (IBAD), sputtering, evaporation, plasma-enhanced chemical vapor deposition (PECVD), expanding thermal plasma CVD (ETPCVD), high intensity plasma chemical vapor deposition (HIPCVD) using either an inductively coupled plasma (ICP) or electron cyclotron resonance (ECR), combinations thereof, and the like. In addition, metallic layers may be deposited by an electroplating process. The choice of deposition technique for the barrier layer is based on the material to be deposited, density of the deposited material, and deposition temperature.

Examples of materials suitable for forming the polymeric layers are polyacrylates such as polymers or copolymers of acrylic acid, methacrylic acid, esters of these acids, or acylonitrile; poly(vinyl fluoride); poly(vinylidene chloride); poly(vinyl alcohol); copolymer of vinyl alcohol and glyoxal; PET, parylene, and polymers derived from cycloolefins and their derivatives such as poly(arylcyclobutene) disclosed in U.S. Pat. Nos. 4,540,763 and 5,185,391. Preferably, the polymeric material is one of polyacrylates.

Examples of materials suitable for forming the inorganic layers are metals (the thickness of such metallic films being small enough to render the film substantially transparent), metal carbides, metal oxides, metal nitrides, metal oxycarbides, metal oxynitrides, and carbonitride. Examples of metals are aluminum, silver, copper, gold, platinum, palladium, and alloys thereof. Preferred metals are aluminum and silver. Examples of metal oxides are ITO, tin oxide, silicon oxides, indium oxide, zinc oxide, aluminum oxide, magnesium oxide, composites thereof, and solutions thereof. Preferred metal oxides are ITO, tin oxide, aluminum oxide, and silicon dioxide. Examples of metal nitrides are nitrides of Groups IVA, VA, VIA, IIIB, and IVB of the Periodic Table. Preferred metal compounds are silicon nitride, silicon oxynitride, silicon oxycarbide, aluminum nitride, and aluminum oxynitride.

The OELD module of the present invention may comprise any type of organic light emitting device. The term “light” includes visible light as well as UV and IR radiation. The OELD module includes an organic electroluminescent (EL) layer disposed on a polymeric substrate of formula (I). The term OELD module generally refers to the combination which includes an organic electroluminescent material, the cathode, the anode, and the device substrate and which may also include other elements such as at least one barrier layer, at least one substantially transparent conductive layer, the device electrical contacts, and a photoluminescent layer.

The organic electroluminescent layer includes the organic electroluminescent material sandwiched between two electrodes, e.g., a cathode and an anode. The organic light emitting layer emits light upon application of a voltage across the anode and cathode from the voltage source. The anode and cathode inject charge carriers, i.e., holes (positive charge) and electrons (negative charge), into the organic light emitting layer where they recombine to form excited molecules or excitons which emit light when the molecules or excitons decay. The color of light emitted by the molecules depends on the energy difference between the excited state and the ground state of the molecules or excitons. Typically, the applied voltage is about 3-10 volts but can be up to 30 volts or more, and the external quantum efficiency (photons out/electrons in) is between 0.01% and 5%, but could be up to 10%, 20%, 30%, or more. The organic electroluminescent layer typically has a thickness in a range between about 50 nanometers and about 500 nanometers, and the anode and cathode each typically have a thickness in a range between about 10 nanometers and about 1000 nanometers.

In an organic electroluminescent device, the polymeric substrate of the present invention is first provided. Optionally, a barrier layer may be present on at least one surface of the substrate. A first electrically conducting material is deposited on one surface of the substrate to form a first electrode. The first electrode may be an anode or a cathode. The first electrode material is preferably sputter-deposited on the substrate. Furthermore, the first electrode may be patterned to a desired configuration by, for example, etching. At least one organic electroluminescent material is deposited on the first electrode by physical or chemical vapor deposition, spin coating, dip coating, spraying, ink-jet printing, or casting, followed by polymerization, if necessary, or curing of the material. The organic electroluminescent material may be diluted in a solvent to adjust its viscosity or mixed with another polymeric material that serves as a film-forming vehicle. A second electrically conducting material is deposited on the at least one organic electroluminescent material to form a second electrode which is a counter-electrode to the first electrode. The second electrode may be deposited on the entire area of the organic electroluminescent material or patterned into a desired shape or configuration. At least one of the electrodes is substantially transparent. Optionally, a substantially transparent conductive layer may be present and is typically disposed between the polymeric substrate and the organic electromagnetic layer.

The cathode generally comprises a material having a low work function value such that a relatively small voltage causes emission of electrons from the cathode. The cathode may comprise, for example, potassium lithium, sodium, magnesium, lanthanum, cesium, calcium, strontium, barium, aluminum, silver, indium, tin, zinc, zirconium, samarium, europium, alloys thereof, or mixtures thereof. Preferred materials for the manufacture of cathode layer are Ag—Mg, Al—Li, In—Mg, and Al—Ca alloys. Layered non-alloy structures are also possible, such as a thin layer of a metal such as Ca (thickness from about 1 to about 10 nm) or a non-metal such as LiF, covered by a thicker layer of some other metal, such as aluminum or silver. Alternatively, the cathode can be made of two layers to enhance electron injection. Examples include a thin inner layer of lithium fluoride (LiF) followed by a thicker outer layer of aluminum or silver, or a thin inner layer of calcium followed by a thicker outer layer of aluminum or silver.

The anode typically comprises a material having a high work function value. The anode is preferably transparent so that light generated in the organic light emitting layer can propagate out of the OELD module. The anode may comprise, for example, indium tin oxide (ITO), tin oxide, indium oxide, zinc oxide, indium zinc oxide, cadmium tin oxide, nickel, gold, or combinations thereof. The electrodes can be formed by conventional vapor deposition techniques, such as evaporation or sputtering, for example.

The organic electroluminescent layer serves as the transport medium for both holes and electrons. In this layer these excited species combine and drop to a lower energy level, concurrently emitting EM radiation in the visible range. Organic electroluminescent materials are chosen to electroluminesce in the desired wavelength range. The organic EL material may be a polymer, a copolymer, a mixture of polymers, or lower molecular-weight organic molecules having unsaturated bonds. Such materials possess a delocalized π-electron system, which gives the polymer chains or organic molecules the ability to support positive and negative charge carriers with high mobility. Suitable electroluminescent polymers are poly(n-vinylcarbazole) (“PVK”, emitting violet-to-blue light in the wavelengths of about 380-500 nm); poly(alkylfluorene) such as poly(9,9-dihexylfluorene) (410-550 nm), poly(dioctylfluorene) (wavelength at peak EL emission of 436 nm), or poly{9,9-bis(3,6-dioxaheptyl)-fluorene-2,7-diyl } (400-550 nm); poly(praraphenylene) derivatives such as poly(2-decyloxy-1,4-phenylene) (400-550 nm). Mixtures of these polymers or copolymers based on one or more of these polymers and others may be used to tune the color of emitted light.

Another class of suitable EL polymers is the polysilanes. Polysilanes are linear silicon-backbone polymers substituted with a variety of alkyl and/or aryl side groups. They are quasi one-dimensional materials with delocalized σ-conjugated electrons along polymer backbone chains. Examples of polysilanes are poly(di-n-butylsilane), poly(di-n-pentylsilane), poly(di-n-hexylsilane), poly(methylphenylsilane), and poly{bis(p-butylphenyl)silane} which are disclosed in H. Suzuki et al., “Near-Ultraviolet Electroluminescence From Polysilanes,” 331 Thin Solid Films 64-70 (1998). These polysilanes emit light having wavelengths in the range from about 320 nm to about 420 nm.

Organic materials having molecular weight less than about 5000 that are made of a large number of aromatic units are also applicable. An example of such materials is 1,3,5-tris{n-(4-diphenylaminophenyl) phenylamino}benzene, which emits light in the wavelength range of 380-500 nm. The organic EL layer also may be prepared from lower molecular weight organic molecules, such as phenylanthracene, tetraarylethene, coumarin, rubrene, tetraphenylbutadiene, anthracene, perylene, coronene, or their derivatives. These materials generally emit light having maximum wavelength of about 520 nm. Still other suitable materials are the low molecular-weight metal organic complexes such as aluminum-, gallium-, and indium-acetylacetonate, which emit light in the wavelength range of 415-457 nm, aluminum-(picolymethylketone)-bis {2,6-di(t-butyl)phenoxide} or scandium-(4-methoxy-picolylmethylketone)-bis(acetylacetonate), which emits in the range of 420-433 nm. For white light application, the preferred organic EL materials are those emit light in the blue-green wavelengths.

More than one organic electroluminescent material may be disposed successively on top of one another, each layer comprising a different organic electroluminescent material that emits in a different wavelength range. Such a construction can facilitate a tuning of the color of the light emitted from the overall light-emitting device.

Furthermore, one or more additional layers may be included to increase the efficiency of the overall device. For example, these additional layers can serve to improve the injection (electron or hole injection enhancement layers) or transport (electron or hole transport layers) of charges into the organic electroluminescent layer. The thickness of each of these layers is kept to below 500 nm, preferably below 100 nm. Materials for these additional layers are typically low-to-intermediate molecular weight (less than about 2000) organic molecules. They may be applied during the manufacture of the device by conventional methods such as spray coating, dip coating, or physical or chemical vapor deposition. In one embodiment of the present invention, a hole injection enhancement layer is formed between the anode layer and the organic electroluminescent material to provide a higher injected current at a given forward bias and/or a higher maximum current before the failure of the device. Thus, the hole injection enhancement layer facilitates the injection of holes from the anode. Suitable materials for the hole injection enhancement layer are arylene-based compounds disclosed in U.S. Pat. No. 5,998,803; such as 3,4,9,10-perylenetetra-carboxylic dianhydride or bis(1,2,5-thiadiazolo)-p-quinobis(1,3-dithiole).

In another embodiment of the present invention, a hole transport layer may be disposed between the hole injection enhancement layer and the organic electroluminescent material. The hole transport layer has the functions of transporting holes and blocking the transportation of electrons so that holes and electrons are optimally combined in the organic electroluminescent material. Materials suitable for the hole transport layer are triaryldiamine, tetraphenyldiamine, aromatic tertiary amines, hydrazone derivatives, carbazole derivatives, triazole derivatives, imidazole derivatives, oxadiazole derivatives having an amino group, and polythiophenes as disclosed in U.S. Pat. No. 6,023,371.

In still another embodiment of the present invention, an additional layer may be disposed between the cathode layer and the organic electroluminescent material. The additional layer has the combined function of injecting and transporting electrons to the organic electroluminescent material. Materials suitable for the electron injecting and transporting layer are metal organic complexes such as tris(8-quinolinolato)aluminum, oxadiazole derivatives, perylene derivatives, pyridine derivatives, pyrimidine derivatives, quinoline derivatives, quinoxaline derivatives, diphenylquinone derivatives, and nitro-substituted fluorene derivatives, as disclosed in U.S. Pat. No. 6,023,371.

The above examples of organic light emitting layers can be used to design an organic light emitting device which emits in one or more desired colors. For example, the OELD module can emit ultraviolet, blue, green, or red light.

The optional barrier layer of the organic electroluminescent device may be a single layer or multilayered. The barrier layer serves as a protective layer to prevent or substantially reduce the diffusion of oxygen and water vapor through the polymeric substrate. The barrier coating may be disposed on either surface of the polymeric substrate or it may completely surround the polymeric substrate. Preferably, the barrier coating is disposed on a surface of the polymeric substrate adjacent to the organic electroluminescent member. When the barrier coating is disposed on a surface of the polymeric substrate opposite the organic electroluminescent member, such a barrier coating may be advantageously formed so to cover substantially all edges of the polymeric substrate. Alternatively, at least one barrier coating can be disposed on either surface of the organic electroluminescent layer. Materials suitable for the barrier layer of the organic electroluminescent device are described above.

The substantially transparent conductive layer and materials for such optional additional layers for organic electroluminescent devices are described above.

In order that those skilled in the art will be better able to practice the invention, the following examples are given by way of illustration and not by way of limitation.

### EXAMPLE 1

A polycarbonate with the following monomer repeat unit of formula (I), 1,3-bis(4-hydroxyphenyl)menthane was manufactured into a film resin material. The aliphatic and isotropic nature of the monomer results in a material with an anisotropy lower than BPA-polycarbonate. Results can be seen in Table 1.

TABLE 1

| Property | BPA-PC | BHPM-PC |
|---|---|---|
| Refractive index | 1.585 | 1.555 |
| Photoelastic coefficient (Brewsters) | About 80 | About 70 |
| Glass transition temperature | 145° C. | 235° C. |

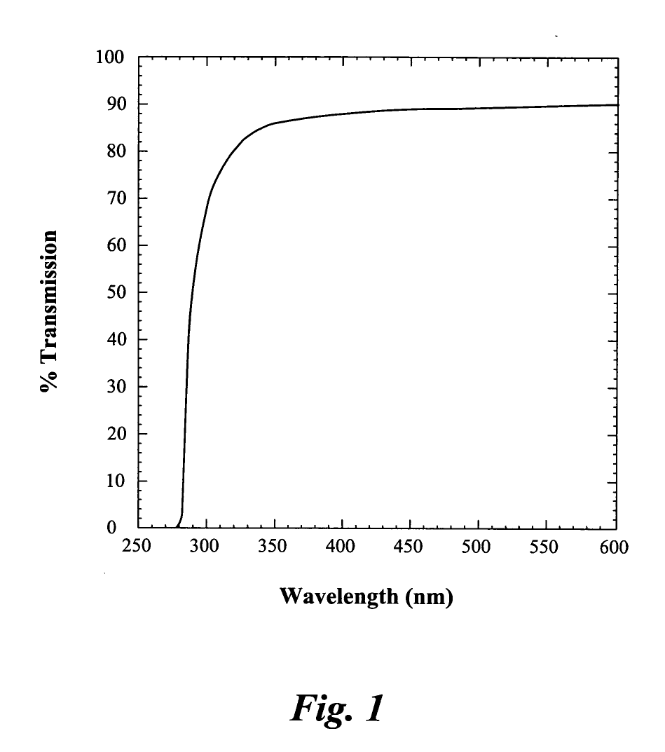

Additionally, a BHPM-PC is substantially transparent, as evidence in the % transmission trace seen in FIG. 1.

While typical embodiments have been set forth for the purpose of illustration, the foregoing description should not be deemed to be a limitation on the scope of the invention. Accordingly, various modifications, adaptations, and alternatives may occur to one skilled in the art without departing from the spirit and scope of the present invention.

What is claimed is: Polymer:

1. A polymeric substrate comprising formula (I): 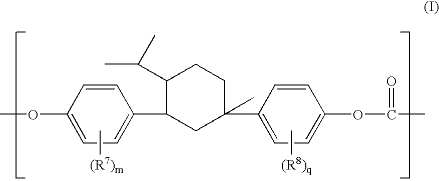
where the three optically active sites of (I) can be R isomers, S isomers, or combinations thereof;
R⁷ and R⁸ are independently selected from the group consisting of C₁-C₆ alkyl and hydrogen;
m is an integer in a range between about 1 and about 4;
q is an integer in a range between about 1 and about 4; and
wherein the polymeric substrate is used in an optical display device or light emitting device.

2. The polymeric substrate in accordance with claim 1, wherein R⁷ and R⁸ are hydrogen, m is 4 and q is 4.

3. The polymeric substrate in accordance with claim 1, having a glass transition temperature greater than about 235° C.

4 The polymeric substrate in accordance with claim 1, having a haze less than about 4%.

5 The polymeric substrate in accordance with claim 1, wherein the polymeric substrate has a uniform thickness that varies less than about 3%.

6 The polymeric substrate in accordance with claim 1, wherein the optical display device is a liquid crystal display.

7. The polymeric substrate in accordance with claim 1, wherein the light emitting device is an organic electroluminescent device.

8 The polymeric substrate in accordance with claim 1, wherein the polymeric substrate comprises at least one barrier layer.

9 The polymeric substrate in accordance with claim 8, wherein the barrier layer comprises an inorganic material, organic material, or combinations thereof.

10 The polymeric substrate in accordance with claim 1, wherein the polymeric substrate comprises at least one substantially transparent conductive layer.

11 The polymeric substrate in accordance with claim 10, wherein said substantially transparent conductive layer comprises an oxide of at least one metal selected from the group consisting of tin, cadmium, indium, zinc, magnesium, gallium, and combinations thereof.

12. The polymeric substrate in accordance with claim 11, wherein said substantially transparent conductive layer further comprises at least one dopant selected from the group consisting of gallium, aluminum, germanium, and tin.

13 The polymeric substrate in accordance with claim 12, wherein said oxide is indium tin oxide.

14 A polymeric substrate comprising formula (I): 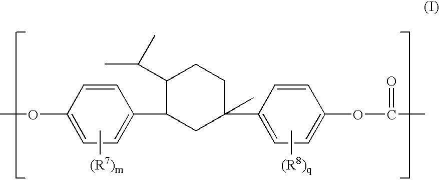
where the three optically active sites of (I) can be R isomers, S isomers, or combinations thereof;
R⁷ and R⁸ are hydrogen;
m is 4; and
q is 4;
wherein the polymeric substrate is used in an optical display device, wherein the polymeric substrate further comprises at least one barrier layer and at least one substantially transparent conductive layer.

15 A method for using a polymeric substrate comprising disposing said polymeric substrate in an optical display device or a light emitting device, wherein said polymeric substrate comprises formula (I): 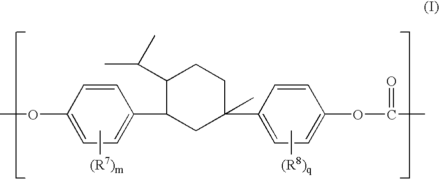
where the three optically active sites of (I) can be R isomers, S isomers, or combinations thereof;
R⁷ and R⁸ are independently selected from the group consisting of C₁-C₆ alkyl and hydrogen;
m is an integer in a range between about 1 and about 4;
q is an integer in a range between about 1 and about 4.

16 The method in accordance with claim 15, wherein R⁷ and R⁸ are hydrogen, m is 4 and q is 4.

17 The method in accordance with claim 15, wherein the polymeric substrate has a glass transition temperature greater than about 235° C.

18 The method in accordance with claim 15, wherein the polymeric substrate has a haze less than about 4%.

19 The method in accordance with claim 15, wherein the polymeric substrate has a uniform thickness that varies less than about 3%.

20 The method in accordance with claim 15, wherein the optical display device is a liquid crystal display device.

21 The method in accordance with claim 15, wherein the light emitting device is an organic electroluminescent device.

22 The method in accordance with claim 15, wherein the polymeric substrate further comprises at least one barrier layer.

23 The method in accordance with claim 22, wherein the barrier layer comprises an inorganic material, organic material, or combinations thereof.

24 The method in accordance with claim 15, wherein the polymeric substrate further comprises at least one substantially transparent conductive layer.

25 The method in accordance with claim 24, wherein said substantially transparent conductive layer comprises an oxide of at least one metal selected from the group consisting of tin, cadmium, indium, zinc, magnesium, gallium, and combinations thereof.

26 The method in accordance with claim 25, wherein said substantially transparent conductive layer further comprises at least one dopant selected from the group consisting of gallium, aluminum, germanium, and tin.

27 The method in accordance with claim 26, wherein said oxide is indium tin oxide.

28 A liquid crystal display comprising:
a) two polymeric substrates, said two polymeric substrates being substantially parallel to each other, wherein each polymeric substrate comprises formula (I): 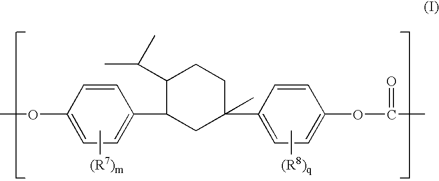
where the three optically active sites of (I) can be R isomers, S isomers, or combinations thereof;
R⁷ and R⁸ are independently selected from the group consisting of C₁-C₆ alkyl and hydrogen;
m is an integer in a range between about 1 and about 4;
q is an integer in a range between about 1 and about 4;
b) a transparent conductive layer disposed on a surface of each of said polymeric substrate; and
c) a liquid crystal material, said liquid crystal material being disposed between said two polymeric substrates, such that said liquid crystal material contacts said transparent conductive layer on each of said two substrates.

29 . The liquid crystal display in accordance with claim 28, wherein R⁷ and R⁸ are hydrogen, m is 4 and q is 4.

30 The liquid crystal display in accordance with claim 28, wherein the polymeric substrate has a glass transition temperature greater than about 235° C.

31 The liquid crystal display in accordance with claim 28, wherein the polymeric substrate has a haze less than about 4%.

32 The liquid crystal display in accordance with claim 28, wherein said liquid crystal material is a liquid crystal material selected from the group consisting of nematic liquid crystals, thermochromic liquid crystals, liotropic liquid crystals, ferroelectric liquid crystals, twisted nematic liquid crystals, super twisted nematic liquid crystals, and polymer-dispersed liquid crystals.

33 The liquid crystal display in accordance with claim 28, wherein the polymeric substrate has a uniform thickness that varies less than about 3%.

34 The liquid crystal display in accordance with claim 28, wherein said transparent conductive layer comprises an oxide of at least one metal selected from the group consisting of tin, cadmium, indium, zinc, magnesium, gallium, and combinations thereof.

35 The liquid crystal display in accordance with claim 34, wherein said transparent conductive layer further comprises at least one dopant selected from the group consisting of gallium, aluminum, germanium, and tin.

36 The liquid crystal display in accordance with claim 35, wherein said oxide is indium tin oxide.

37 The liquid crystal display in accordance with claim 28, wherein at least one barrier layer is disposed on at least one surface of the polymeric substrate.

38 The liquid crystal display in accordance with claim 37, wherein the at least one barrier layer comprises an inorganic material, organic material, or combinations thereof.

39 An organic electroluminescent device comprising
(a) a polymeric substrate wherein said polymeric substrate comprises formula (I): 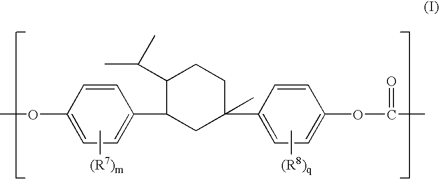
where the three optically active sites of (I) can be R isomers, S isomers, or combinations thereof;
R⁷ and R⁸ are independently selected from the group consisting of C₁-C₆ alkyl and hydrogen;
m is an integer in a range between about 1 and about 4; and
q is an integer in a range between about 1 and about 4
(b) an organic electroluminescent layer disposed on the polymeric substrate, wherein the organic electroluminescent layer comprises an organic electroluminescent material disposed between two electrodes.

40 The organic electroluminescent device in accordance with claim 39, wherein the R⁷ and R⁸ are hydrogen, m is 4, and q is 4.

41 The organic electroluminescent device in accordance with claim 39, wherein the polymeric substrate has a glass transition temperature greater than about 235° C.

42 The organic electroluminescent device in accordance with claim 39, wherein the polymeric substrate has a haze less than about 4%.

43 The organic electroluminescent device in accordance with claim 39, wherein the polymeric substrate has a uniform thickness that varies less than about 3%.

44 The organic electroluminescent device in accordance with claim 39, wherein at least one barrier layer is disposed on at least one surface of the polymeric substrate.

45 The organic electroluminescent device in accordance with claim 44, wherein the at least one barrier layer comprises an inorganic material, organic material, or combinations thereof.

46 The organic electroluminescent device in accordance with claim 39, wherein at least one transparent conductive layer is disposed between the organic electroluminescent layer and the polymeric substrate layer.

47 . The organic electroluminescent device in accordance with claim 46, wherein said transparent conductive layer comprises an oxide of at least one metal selected from the group consisting of tin, cadmium, indium, zinc, magnesium, gallium, and combinations thereof.

48 The organic electroluminescent device in accordance with claim 47, wherein said transparent conductive layer further comprises at least one dopant selected from the group consisting of gallium, aluminum, germanium, and tin.

49 The organic electroluminescent device in accordance with claim 48, wherein said oxide is indium tin oxide.

50 The organic electroluminescent device in accordance with claim 39, wherein said organic electroluminescent material is selected from the group consisting of poly(n-vinylcarbazole), poly(alkylfluorene), poly(paraphenylene), polysilanes, derivatives thereof, mixtures thereof, and copolymers thereof.

51 The organic electroluminescent device in accordance with claim 39, wherein said organic electroluminescent material is selected from the group consisting of 1,2,3-tris{n-(4-diphenylaminophenyl) phenylamino}benzene, phenylanthracene, tetraarylethene, coumarin, rubrene, tetraphenylbutadiene, anthracene, perylene, coronene, aluminum-(picolymethylketone)-bis{2,6-di(t-butyl)phenoxide, scandium-(4-methoxy-picolymethylketone)-bis(acetylacetonate), aluminum-acetylacetonate, gallium-acetylacetonate, and indium-acetylacetonate.

52 The organic electroluminescent device in accordance with claim 39, wherein one of said two electrodes is an anode which is disposed on said substrate, and said anode comprises a material selected from the group consisting of indium tin oxide (“ITO”), tin oxide, indium oxide, zinc oxide, indium zinc oxide, cadmium tin oxide, mixtures thereof, and these oxides doped with aluminum or fluorine.

53 The organic electroluminescent device in accordance with claim 39, wherein a second of said two electrodes is a cathode and comprises a material selected from the group consisting of K, Li, Na, Mg, La, Ce, Ca, Sr, Ba, Al, Ag, In, Sn, Zn, Zr, Sm, Eu, alloys thereof, and mixtures thereof.
